(19) United States
(12) Patent Application Publication
(10) Pub. No.: US 2018/0145274 A1
(43) Pub. Date: May 24, 2018

(54) ORGANIC EMITTER LAYER, ORGANIC LIGHT-EMITTING DIODE AND USE OF HEAVY ATOMS IN AN ORGANIC EMITTER LAYER OF AN ORGANIC LIGHT-EMITTING DIODE

(71) Applicant: OSRAM OLED GmbH, Regensburg (DE)

(72) Inventors: Andreas RAUSCH, Regensburg (DE); Dominik PENTLEHNER, Burghausen (DE)

(21) Appl. No.: 15/571,501

(22) PCT Filed: May 4, 2016
(86) PCT No.: PCT/EP2016/060026

§ 371 Date: Nov. 2, 2017

(30) Foreign Application Priority Data
May 5, 2015 (DE) 10 2015 106 941.5

(51) Int. Cl. H01L 51/50; H01L 51/52

(52) U.S. Cl. CPC H01L 51/5028; H01L 51/5206; H01L 51/5221; H01L 51/5016; H01L 51/5096; H01L 51/5088; H01L 51/5092

(57) ABSTRACT

The invention relates to an organic emitter layer (100) having organic emitter molecules (1), each of which has at least one excited triplet state (SE1) and at least one excited singlet state (TE1). The emitter layer (100) comprises an organic matrix material (10) with first matrix molecules (2), the first matrix molecules (2) having at least one excited triplet state (TA1) and at least one excited singlet state (SA1). The emitter molecules (1) are embedded into the matrix material (10). During the operation of the emitter layer (100), the triplet states and the singlet states of the first matrix molecules (2) are excited, and the excitation energy is then transferred to the emitter molecules such that the singlet states are excited in the emitter molecules. A transition occurs from the singlet states of the emitter molecules (1) into the base state (SE0), thereby at least partially emitting electromagnetic radiation. In the first matrix molecules, the value of the energy level difference I ΔE (SA1−TA1) I between the triplet state and the singlet state is maximally 2500 cm−1. A time constant TA for the transition from the triplet state into the singlet state in the first matrix molecules is maximally 1·10−6 s. Heavy atoms (3) with an atomic number of at least 16 are intentionally introduced into the matrix material

An organic emitter layer is provided. In addition, an organic light-emitting diode is provided. Furthermore, the use of heavy atoms in an emitter layer of an organic light-emitting diode is provided.

One object to be achieved is to provide an organic emitter layer having a particularly high luminous efficiency or quantum efficiency. Further objects to be achieved consist in providing an organic light-emitting diode, OLED for short, having such an emitter layer, as well as the use of heavy atoms in an emitter layer of an OLED.

These objects are achieved by the subjects of the independent patents claims. Advantageous embodiments and further developments are the subject-matter of the dependent claims.

According to at least one embodiment, the organic emitter layer includes organic emitter molecules each having at least one excited triplet state and at least one excited singlet state. Here, an excited state is a state being higher than the ground state of the molecule in terms of energy. During operation of the emitter layer, the triplet and singlet states of the emitter molecules can be excited. The triplet state is a spin S=1 state, the singlet state is a spin S=0 state. Here, each triplet state can be occupied with three configurations, mₛ=−1, 0, 1, the singlet state can only be occupied in one configuration mₛ=0.

According to at least one embodiment, the emitter layer comprises an organic matrix material which includes organic first matrix molecules. The matrix material can thus be a mix of various organic and inorganic molecules, part of the organic molecules or all organic molecules being organic first matrix molecules. The first matrix molecules each have at least one excited triplet state and at least one excited singlet state. The triplet and singlet states of the first matrix molecules can also be excited during operation of the emitter layer.

In general, the triplet state is lower in terms of energy than the respective singlet state in both the emitter molecules and the first matrix molecules.

According to at least one embodiment, the emitter molecules are embedded in the matrix material. That is, in particular, the emitter molecules are partially or completely surrounded by the matrix material and the first matrix molecules. Thus, the emitter layer is preferably a homogenous mix of emitter molecules and the matrix material.

According to at least one embodiment, the singlet states and the triplet states of the first matrix molecules are excited or occupied during the operation of the emitter layer. The excitation can be achieved either by electric or by optic excitation.

The emitter layer is e.g. arranged between two electrodes, an anode and a cathode. Electrons can enter the emitter layer from the cathode, holes can enter the emitter layer from the anode. An electron and a hole can form an exciton when they are located close enough. For example, first a hole is trapped within a first matrix molecule, this hole subsequently forming an exciton with an approaching electron. The exciton can be formed either in the spin singlet state, S=0, or in the spin triplet state, S=1. If the electron of the exciton is close enough to the first matrix molecule with the respective hole, the electron can jump into the first matrix molecule in a rapid process and thus occupy an excited state in the first matrix molecule. Depending on whether the previously-formed exciton was an S=0 exciton or an S=1 exciton, the singlet or triplet states can be taken in this way.

The functionality of organic emitter layers, in particular the excitation of molecules via excitons, is described in patent document DE 10 2011 089 687 A1, or also in the paper “The triplet state of organo-transition metal compounds. Triplet harvesting and singlet harvesting for efficient OLEDs” by Hartmut Yersin et al., Coordination Chemistry Reviews, Volume 255, Issues 21-22, November 2011, pages 2622-2652, for example.

However, as an alternative, it is also possible to have the singlet states or triplet states of the first matrix molecules occupied by optical excitation, so-called photoexcitation, e.g. by irradiation of electromagnetic radiation.

According to at least one embodiment, the excitation energy of the triplet states and the singlet states of the first matrix molecules is at least partially transmitted to the emitter molecules during operation of the emitter layer, so that the singlet states of the emitter molecules are excited or occupied. That is, preferably first the first matrix molecules are excited during operation, and in some or all cases, at least part of the respective excitation energy is transmitted to the emitter molecules, so that the emitter molecules are excited.

According to at least one embodiment, transitions from the singlet states of the emitter molecules to the ground state occur while at least partially emitting electromagnetic radiation. Thus, the emitter molecules are configured to emit electromagnetic radiation during the intended operation of the emitter layer. Besides the radiating transition from an excited state into the ground state, a non-radiating transition is conceivable as well.

According to at least one embodiment, the absolute value of the energy level difference |ΔE(S_{A1}−T_{A1})| between the triplet state T_{A1} and the singlet state S_{A1} of the first matrix molecules is 2,500 cm⁻¹ at most, or 1000 cm⁻¹ at most, or 500 cm⁻¹ at most. In this case, the energy is expressed by the wave number k, wherein the wave number k corresponds to the reciprocal value of the wavelength λ, of a photon having the energy |ΔE(S_{A1}−T_{A1})|. The conversion between energy and wavenumber is done by the following formula:

$$E = \frac{h \cdot c}{λ} = h \cdot c \cdot k \qquad ( 1 )$$

The wave number of k=2500 cm⁻¹ corresponds to approximately 0.30996 eV. The split between the triplet state and the singlet state of the first matrix molecules is therefore selected small, so that according Boltzmann statistics, a thermal transition between the triplet and singlet states of the first matrix molecules is also possible at room temperature (k_{B}T=8.617·10⁻⁵ eV/K·298 K=0.026 eV). In particular, the organic emitter layer is operated also at room temperature or at temperatures between 40° C. and +100° C. inclusive.

According to at least one embodiment, the time constant T_{A} for the transition from the triplet state to the singlet state is at most 1·10⁻⁶ s, or at most 1·10⁻⁷ s, or at most 1·10⁻⁸ s, or at most 1·10⁻⁹ s, or at most 1·10⁻¹⁰ s. This triplet-singlet transition is also referred to as inter-system-crossing, ISC for short. Such processes are also known from DE 10 2011 089 687 A1, for example. The transition probability between the triplet state and the singlet state (ISC process) and therefore the time constant τ_{A} depends among others on the intensity of the spin-orbit coupling.

According to at least one embodiment, heavy atoms are intentionally introduced in the matrix material, in particular heavy atoms with an atomic number of at least 16. Here, the atomic number 16 corresponds to the element Sulphur.

In at least one embodiment, the organic emitter layer comprises organic emitter molecules each having at least one excited triplet state and at least one excited singlet state.

The emitter layer further comprises an organic matrix material which includes organic first matrix molecules, wherein the first matrix molecules have at least one excited triplet state and at least one excited singlet state. Here, the emitter molecules are embedded in the matrix material. During operation of the emitter layer, the triplet and singlet states of the first matrix molecules are excited, the excitation energy is subsequently transmitted to the emitter molecules so that the singlet states are excited there. A transition from the singlet states of the emitter molecules to the ground state occurs while at least partially emitting electromagnetic radiation during operation. Here, the absolute value of the energy level difference |ΔE(S_{A1}−T_{A1})| between the triplet state and the singlet state of the first matrix molecules is 2500 cm⁻¹ at most. In the first matrix molecules the time constant T_{A} for the transition from the triplet state to the singlet state is 1·10⁻⁶ s, at the most. Furthermore, heavy atoms with an atomic number of at least 16 are intentionally introduced in the matrix material.

Organic light-emitting diodes use organic light-emitting molecules which are being excited during operation. Upon transition to the ground state, electromagnetic radiation is emitted. Normally, transition to the ground state occurs either from a triplet state or a singlet state. Due to the spin statistics, 75% of the excitations lead to excitations into the triplet state, and only 25% of the excitations lead to excitations in the singlet state. Due to the fact that the ground state is largely also a singlet state, the radiating transition from the excited singlet state to the ground state is strongly allowed with typical life spans of 1 ns to 100 ns. This rapid radiating transition is referred to as fluorescence.

The transition from the triplet state to the ground state is generally strongly suppressed due to the often low spin orbit coupling in purely organic molecules, which is why the time constant for the transition becomes large, e.g. ≥100 μs or ≥1 ms. The radiating transition from the triplet state to the singlet state, also referred to as phosphorescence, strongly competes with non-radiating transitions. Non-radiating transitions are often predominant then. In the worst case, 75% of excitations, i.e. all triplet-state excitations, get lost, i.e. recombine without emitting radiation.

This point of view explains why the internal quantum efficiency, i.e. the number of excited photons per excitation, is only 25% at most in such fluorescent emitter materials or light-emitting diodes.

Inter alia, the invention described herein makes use of the idea to not directly excite the emitter molecules, but to first excite first matrix molecules and to cause the singlet states to be occupied more often within the first matrix molecules. The excitation energy is transferred to the emitter molecules then. In this process, excited singlet states in the emitter molecules result from the excited singlet states of the first matrix molecules.

In the present invention, the energy split-off between the triplet state and the singlet state in the first matrix molecules is selected such small that, due to thermal excitations, a transition from the triplet state which usually is lower in terms of energy than the respective singlet state—to the singlet state becomes possible (ISC process). The value mentioned above, according to which only 25% of excitations lead to an excited singlet state, can therefore be increased to a higher percentage. Upon the transfer of the excitation to the emitter molecules, a higher percentage of the singlet states is occupied in the emitter molecules, whereby the internal quantum efficiency can be increased to more than 25%.

Due to the fact however that for the thermal excitation in the first matrix molecules from the triplet state to the singlet state, not only the energy level difference |ΔE(S_{A1}−T_{A1})| of the two states is decisive, but also the spin-orbit coupling, the following invention has heavy atoms intentionally introduced in the matrix material. The additional heavy atoms effect an additional, preferably strongly-increased spin-orbit coupling in the first matrix molecules. In the first matrix molecules, this coupling additionally increases the transition probability from the triplet state to the singlet state. Together with the low energy level difference |ΔE(S_{A1}−T_{A1})|, this achieves a particularly efficient occupation of the singlet states from the triplet states, so that a large part of the excitations produced in the emitter layer leads to excitations in the emitter molecules, which then decompose into the ground state while being fluorescent. Compared to conventional organic emitter layers, the emitter layer described herein has a particularly high quantum efficiency.

The energy split |ΔE(S_{A1}−T_{A1})| between the triplet state and the singlet state present in the first matrix molecule can be determined in different ways. One option is to determine the energy split by means of quantum mechanical calculations by means of known computer programs. TDDFT calculations with commercially available Gaussian 09 or ADF Amsterdam Density Functional software programs (see also DE 10 2011 089 687 A1) are suitable to that end, for example.

Besides that, there is also the option to determine the energy split between the triplet state und and the singlet states by experiment. The intensity ratio of fluorescence and phosphorescence, i.e. the ratio of the intensity of the transition of the singlet state to the ground state (Int(S₁→S₀)) relative to the intensity of the transition of the triplet state to the ground state (Int(T₁→S₀) is obtained as follows, (see DE 10 2011 089 687 A1):

$$\vert \frac{Int ( {S}_{1} -> {S}_{0} )}{Int ( {S}_{1} -> {S}_{0} )} = \frac{k ( {S}_{1} )}{k ( {T}_{1} )} \cdot exp ( \frac{- Δ E}{{k}_{B} T} ) \qquad ( 2 )$$

Here, k_{B} is the Boltzmann Constant and T is the absolute temperature in Kelvin. k(S₁)/k(T₁) is the transition moment ratio of the transition processes from the singlet state S₁ and from the triplet state T₁ to the electronic ground state S₀. For organic molecules without additional spin-orbit coupling by means of heavy atoms, this transition moment ratio is usually at approximately 10⁴. An additional spin-orbit coupling can increase in particular the transition moment k(T₁).

Equation (2) above can be formed into:

$$ln ( \frac{Int ( {S}_{1} -> {S}_{0} )}{Int ( {T}_{1} -> {S}_{0} )} ) = ln ( \frac{k ( {S}_{1} )}{k ( {T}_{1} )} ) - \frac{Δ E}{{k}_{B} T} \qquad ( 3 )$$

The measurement of the intensities Int(S1→S₀) and Int(T₁→S₀) of the fluorescence and phosphorescence can be performed using commercially available spectrophotometers. If this intensity measurement is performed at different temperatures and if the ratio is plotted as a function 1/T, the energy split ΔE can be determined through the slope of the resulting straight line.

The transition probability from a triplet to a singlet state (ISC process) and therefore the time constant τ_{A} can be determined by means of experiments. One option to perform such a measurement is shown in “Direct Observation of the Intersystem Crossing in Poly(3-Octylthiophene)” by B. Kraabel et al., J. Chem. Phys., Volume 103, N^{o} 12, 1995, for example.

According to at least one embodiment, the heavy atoms intentionally-introduced cause an increased spin-orbit coupling in the matrix material in the first matrix molecules, such that the time constant τ_{A} is set.

According to at least one embodiment, the emitter molecules are selected from the group of the following molecules or molecule classes: DCM (4-(Dicyanomethylene)-2-methyl-6-(p-dimethylamino-styryle)4H-pyran), DCM2 (4-(dicyanomethylene)-2-methyl-6-(julolidin-4-yl-vinyl)-4H-pyran), Rubrene (5,6,11,12-tetraphenyl-naphthacen), coumarin (C545T), TBSA (9,10-Bis[(2″,7″″-di-t-butyl)-9′,9″-spirobifluorenyl]anthracene), Zn-complexes, Cu-complexes, Aluminum-tris(8-hydroxyquinoline).

According to at least one embodiment, the first matrix molecules are selected from the group of the following molecules or molecule classes: (4,4′-Bis(carbazole-9-yl)-2-2′dimethyl-biphenyl), TCTA (4,4′,4″-Tris(n-(naphth-2-yl)-N-phenyl-amino)triphenylamine), mCP, TCP (1,3,5-tris-carcazol-9-yl-bezene), CDBP (4,4′-Bis(carbazole-9-yl)-2,2′-dimethyl-biphenyl), DPVBi (4,4-Bis(2,2-diphenyl-ethen-1-yl)-diphenyl), Spiro-PVBi (spiro-4,4′-Bis(2,2-diphenyl-ethen-1-yl)-diphenyl), ADN (9,10-Di(2-naphthyl)anthracene), Perylene, carbazole derivates, fluorene derivates, CZ-PS, 2CzPN, m-ATP-ACR, ACRFLCN, PTZ-TRZ, CC2BP, BDPCC-TPTA, DPAA-AF, AcPmBPX. PIC-TRZ2, ACRSA, 4CzIPN, PxPmBPX, DHPT-2Bi, m-ATP-PXZ, 2PXZ-OXD, 4CzTPN, 4CzPN, 3DPA3CN, 4CzTPN-Me, Spiro-CN, 4CzTPN-Ph, DDCzIPN, PPZ-DPO, PPZ-3TPT, PPZ-4TPT, PPZ-DPS, PXZ-DPS, PXZ-TRZ, DMAC-DPS, PXZ-DPS, MAD-DPS, 2,4-bis{3-(9H-carbazole-9-yl)-9H-carbazole-9-yl}-6-phenyl-1,3,5-triazines (CC2TA), 9-(4,6-diphenyl-1,3,5-triazine-2-yl)-90-phenyl-3,30-bicarbazole (CzT).

According to at least one embodiment, the matrix material is selected from the group of the following molecules or molecule classes: CBP (4,4′-Bis(carbazole-9-yl)-2-2′dimethyl-biphenyl), TCTA (4,4′,4″-Tris(n-(naphth-2-yl)-N-phenyl-amino)triphenylamine), mCP, TCP (1,3,5-tris-carcazol-9-yl-bezene), CDBP (4,4′-Bis(carbazole-9-yl)-2,2′-dimethyl-biphenyl), DPVBi (4,4-Bis(2,2-diphenyl-ethen-1-yl)-diphenyl), Spiro-PVBi (spiro-4,4′-Bis(2,2-diphenyl-ethen-1-yl)-diphenyl), ADN (9,10-Di(2-naphthyl)anthracene), Perylene, carbazole derivates, fluorene derivates, CZ-PS, 2CzPN, m-ATP-ACR, ACRFLCN, PTZ-TRZ, CC2BP, BDPCC-TPTA, DPAA-AF, AcPmBPX. PIC-TRZ2, ACRSA, 4CzIPN, PxPmBPX, DHPT-2Bi, m-ATP-PXZ, 2PXZ-OXD, 4CzTPN, 4CzPN, 3DPA3CN, 4CzTPN-Me, Spiro-CN, 4CzTPN-Ph, DDCzIPN, PPZ-DPO, PPZ-3TPT, PPZ-4TPT, PPZ-DPS, PXZ-DPS, PXZ-TRZ, DMAC-DPS, PXZ-DPS, MAD-DPS, 2,4-bis{3-(9H-carbazole-9-yl)-9H-carbazole-9-yl}-6-phenyl-1,3,5-triazines (CC2TA), 9-(4,6-diphenyl-1,3,5-triazine-2-yl)-90-phenyl-3,30-bicarbazole (CzT).

According to at least one embodiment, the heavy atoms are selected from the group of the following elements: S, Br, I, Kr, Xe, metals and metalloids of the third, fourth and fifth main group period, metals of the first, second and third sub group period, elements of the lanthanoids and actinoids.

The heavy atoms are particularly preferably selected from the following group: metals and metalloids of the fourth and fifth main group period, metals of the second and third sub group period, elements of the lanthanoids and actinoids.

The use of heavy atoms, which effect a high spin-orbit coupling within the first matrix molecules, allows increasing the ISC-rate or decreasing the time constant τ_{A}, what further increases the quantum efficiency of the emitter layer.

According to at least one embodiment, during operation of the emitter layer, at least 80% or 90% or 95% or 99% of the resulting primary excitations in the emitter layer are excitations of the singlet states of the first matrix materials. This means that e.g. at least 80% of the electrons and holes input into the emitter layer by electrodes combine to form excitons, which first, i.e. primarily, excite the first matrix molecules and thereby occupy the singlet state and/or first occupy the triplet state in the first matrix molecules and subsequently transfer to the singlet state from the triplet state. Alternatively, also at least 80% or 90% or 95% or 99% of radiation absorbed by the emitter layer can first, i.e. primarily, lead to excitations of the singlet states in the first matrix molecules.

According to at least one embodiment, the first matrix molecules are not provided or configured to emit electromagnetic radiation during operation. In e.g. at most 10% or at most 5 or at most 1% of the cases, the excited first matrix molecules decompose into the ground state of the first matrix molecules. At least 90% or at least 95% or at least 99% of the excitations of the first matrix molecules are transferred to the emitter molecules.

According to at least one embodiment, in the emitter molecules the absolute value of the energy level difference |ΔE(S_{E1}−T_{E1})| between the triplet state and the singlet state is at least 2,500 cm⁻¹, or at least 5,000 cm⁻¹, or at least 7,500 cm⁻¹. A low energy split between triplet and singlet states is not required within the emitter molecules, as in the present invention, the ISC process is to occur in the first matrix molecules and not in the emitter molecules. A large energy split between triplet and singlet states of the emitter molecules decreases the probability for the ISC process within the emitter molecules.

According to at least one embodiment, the triplet state and the singlet state in the first matrix molecules are in each case the first excited triplet state and singlet state above the respective ground state of the first matrix molecules. In particular, even higher triplet and singlet states of the first matrix molecules can be occupied during the operation of the emitter layer, which decompose then preferably in very fast non-radiating processes, so-called internal conversion processes, IC processes for short, to the lowest triplet and singlet states of the first matrix molecules. IC processes typically take place with time constants of a magnitude of 10⁻¹² seconds.

According to at least one embodiment, the triplet state and the singlet state of the emitter molecules are in each case the first excited triplet state and singlet state above the respective ground state of the emitter molecules.

According to at least one embodiment, at least 90% or 95% or 99% of the transitions in the emitter molecules are transitions from the singlet state to the respective ground state. In other words, the emitter layer in particular is a singlet emitter or a fluorescent emitter. As already explained above, the transition from the triplet state to the ground state within the emitter molecules is generally strongly suppressed.

The radiation emitted by the emitter molecules is preferably light in the visible spectral range, e.g. blue light in the spectral range of 420 nm to 510 nm inclusive, and/or green light in the spectral range of 510 nm to 570 nm inclusive, and/or yellow light in the spectral range of 570 nm to 590 nm inclusive, and/or orange light in the spectral range of 590 nm to 610 nm inclusive, and/or red light in the spectral range of 610 nm to 790 nm inclusive.

According to at least one embodiment, the heavy atoms are free or basically free atoms in the matrix material. The heavy atoms are therefore in particular not bound to organic molecules of the matrix materials by coordinative or covalent bonds. Rather, the heavy atoms are in particular exclusively dopant atoms within the matrix material.

According to at least one embodiment, the heavy atoms are at least partially bound through coordinative or covalent bonds in organic or inorganic molecules of the matrix materials. In other words, the matrix material comprises compounds containing heavy atoms, in which heavy atoms are coordinatively or covalently bound to organic or inorganic ligands. Here, the compounds containing heavy atoms are preferably not the first matrix molecules.

According to at least one embodiment, the proportion of the heavy atoms and/or compounds containing heavy atoms in the emitter layer is at least 3 vol.-% or at least 5 vol.-% or at least 15 vol.-% or at least 20 vol.-%.

According to at least one embodiment, the proportion of the first matrix molecules in the emitter layer is at least 10 vol.-% or at least 30 vol.-% or at least 60 vol.-%. Alternatively or in addition, the proportion of first matrix molecules is 96 vol.-% at most, or 80 vol.-% at most, or 70 vol.-% at most.

According to at least one embodiment, the proportion of emitter molecules in the emitter layer is 40 vol.-% at most, or 20 vol.-% at most, or 5 vol.-% at most. Alternatively or in addition, the proportion of the emitter molecules in the emitter layer is at least 1 vol.-% or at least 3 vol.-% or at least 4 vol.-%.

Furthermore, an organic light-emitting diode is provided. The organic light-emitting diode includes for example an organic emitter layer described here. In other words, all features disclosed for the organic emitter layer are also disclosed for the organic light-emitting diode and vice versa.

According to at least one embodiment, the organic light-emitting diode includes an emitter layer as described above. The light-emitting diode preferably comprises an anode and a cathode, between which the emitter layer is arranged. The emitter layer is electrically contacted via the anode and the cathode and electrons and holes respectively are introduced in the emitter layer. The electrons and holes from the cathode and the anode can form excitons then, which excite the triplet and singlet states in the first matrix molecules then.

According to at least one embodiment, the anode and/or cathode are transparent for the radiation emitted by the emitter layer. In particular, the anode and/or cathode is clear-sighted or non-absorbing or milkily opaque for the radiation emitted by the emitter layer. The radiation can exit the organic light-emitting diode and the emitter layer via the transparent anode and/or cathode. The anode and/or cathode can comprise or consist of a transparent conductive oxide, TCO for short, such as indium tin oxide, ITO for short. One of the two cathodes can further comprise or consist of a reflecting, in particular mirroring material, e.g. a metal such as silver or gold or aluminum or titanium.

According to at least one embodiment, an electron injection layer and/or a hole blocking layer is arranged between the cathode and the emitter layer.

According to at least one embodiment, a hole-injection layer and/or an electron blocking layer is arranged between the anode and the emitter layer.

Such injection and blocking layers are known from EP 2422381 A1, for example.

The injection layers are in particular provided for making a transport of electrons and holes respectively towards the emitter layer efficient. The blocking layers are provided to suppress holes from being transported towards the cathode or prevent electrons from being transported towards the anode. Such injection or blocking layers further increase the efficiency of the light-emitting diode.

Furthermore, the use of heavy atoms in an organic emitter layer of an organic light-emitting diode is provided. The organic light-emitting diode is an organic light-emitting diode as described here having an organic emitter layer described here. In other words, all features disclosed in conjunction with the use of heavy atoms in an organic light-emitting diode are also disclosed for the organic light-emitting diode or the organic emitter layer or vice versa.

According to at least one embodiment, heavy atoms with an atomic number of at least 16 are used in an organic emitter layer of an organic light-emitting diode. Here, the organic light-emitting diode includes the organic emitter layer which generates electromagnetic radiation during the intended operation. The organic emitter layer comprises an organic matrix material with first organic matrix molecules. The matrix material has organic emitter molecules embedded therein. The heavy atoms are introduced in the matrix material as free or practically free atoms and/or in the form of compounds containing heavy atoms. In this case, the proportion of heavy atoms and/or compounds containing heavy atoms is at least 3 vol.-% in the emitter layer.

The first matrix molecules are selected from at least one of the following material classes: (4,4′-Bis(carbazole-9-yl)-2-2′dimethyl-biphenyl), TCTA (4,4′,4″-Tris(n-(naphth-2-yl)-N-phenyl-amino)triphenylamine), mCP, TCP (1,3,5-tris-carcazol-9-yl-bezene), CDBP (4,4′-Bis(carbazole-9-yl)-2,2′-dimethyl-biphenyl), DPVBi (4,4-Bis(2,2-diphenyl-ethen-1-yl)-diphenyl), Spiro-PVBi (spiro-4,4′-Bis(2,2-diphenyl-ethen-1-yl)-diphenyl), ADN (9,10-Di(2-naphthyl)anthracene), Perylene, carbazole derivates, fluorene derivates, CZ-PS, 2CzPN, m-ATP-ACR, ACRFLCN, PTZ-TRZ, CC2BP, BDPCC-TPTA, DPAA-AF, AcPmBPX. PIC-TRZ2, ACRSA, 4CzIPN, PxPmBPX, DHPT-2Bi, m-ATP-PXZ, 2PXZ-OXD, 4CzTPN, 4CzPN, 3DPA3CN, 4CzTPN-Me, Spiro-CN, 4CzTPN-Ph, DDCzIPN, PPZ-DPO, PPZ-3TPT, PPZ-4TPT, PPZ-DPS, PXZ-DPS, PXZ-TRZ, DMAC-DPS, PXZ-DPS, MAD-DPS, 2,4-bis{3-(9H-carbazole-9-yl)-9H-carbazole-9-yl}-6-phenyl-1,3,5-triazines (CC2TA), 9-(4,6-diphenyl-1,3,5-triazine-2-yl)-90-phenyl-3,30-bicarbazole (CzT).

The heavy atoms are selected from the following group: metals and metalloids of the third, fourth and fifth main group period, metals of the first, second and third sub group period, elements of the lanthanoids and actinoids.

Furthermore, in the first matrix molecules the absolute value of the energy level difference |ΔE(S_{A1}−T_{A1})| between a first excited triplet state T_{A1} and a first excited singlet state S_{A1} is at most 2,500 cm⁻¹.

An organic emitter layer described herein and an organic light-emitting diode described herein are explained in further detail hereinafter by means of exemplary embodiments with reference to the drawings. Same reference characters indicate same elements throughout the individual figures. However, relations are not to scale and individual elements may rather be illustrated in an exaggerated size for the purpose of better illustration.

The figures show in:

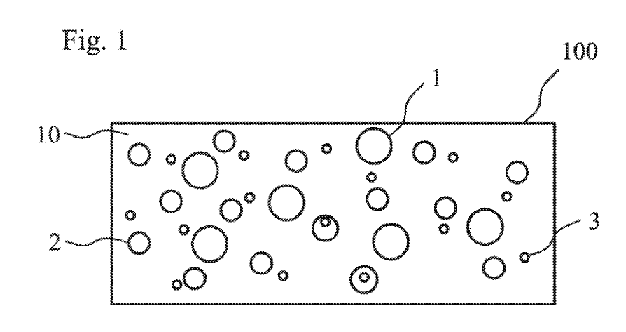

FIG. 1 an exemplary embodiment of an emitter layer in a cross-sectional view,

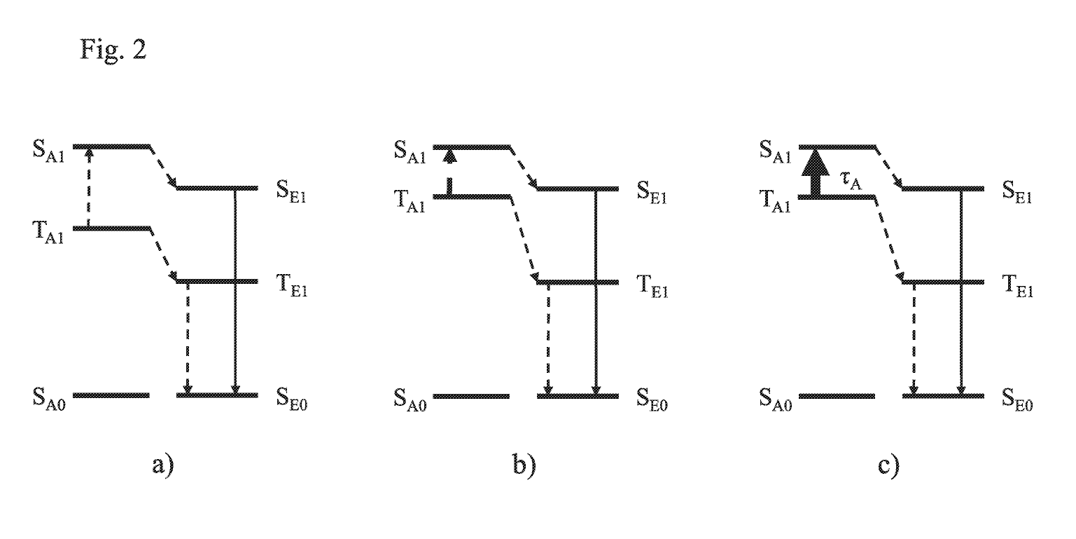

FIG. 2 energy level diagrams of various first matrix molecules and emitter molecules,

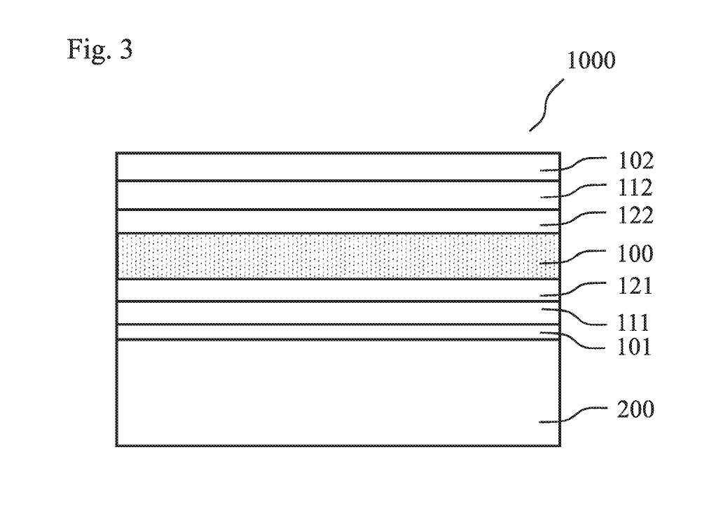

FIG. 3 an exemplary embodiment of an organic light-emitting diode in a cross-sectional view.

FIG. 1 shows an organic emitter layer 100 described herein in a cross-sectional view. The emitter layer 100 comprises an organic matrix material 10 having the emitter molecules 1 embedded therein. Preferably, the emitter molecules 1 are randomly and/or homogenously distributed inside the matrix material 10. Furthermore, the matrix material 10 further includes organic first matrix molecules 2.

During operation of the emitter layer 100, the emitter molecules 1 are configured to generate electromagnetic radiation, in particular visible light by means of a transition from a singlet state S_{E1} to the ground state S_{E0}. Here, the singlet state S_{E1} in the emitter molecules 1 is preferably the first excited singlet state above the ground state S_{E0}. The emitter molecules 1 furthermore comprise a triplet state T_{E1}, which is preferably also the first excited triplet state above the ground state S_{E0}.

Occupying the singlet states S_{E1} within the emitter molecules 1 is largely, e.g. by at least 90%, effected by the transmission of an excitation energy from the first matrix molecules 2 to the emitter molecules 1. During operation of the emitter layer 100, the first matrix molecules 2 are excited electronically, for example. Here, both triplet states T_{A1} and singlet states S_{A1} of the first matrix molecules 2 are excited or occupied. Here, the triplet states T_{A1} and singlet states S_{A1} of the first matrix molecules 2 are the first triplet and singlet states above the ground state S_{A0} of the first matrix molecules 2. The excitation energy of the first molecules 2 can thereafter at least partially be transferred to the emitter molecules 1, for example in at least 90% of the cases, leading to excitation or the occupation of the singlet states S_{E1} in the emitter molecules 1. Upon transition into the ground state S_{E0}, electromagnetic radiation is emitted then. For example, at least 90% of the visible radiation emitted by the emitter layer 100 results from a fluorescence transition from singlet states S_{E1} into the ground state S_{E0} of the emitter molecules 1.

Furthermore, FIG. 1 shows heavy atoms 3, which are either embedded as free or practically free atoms inside the matrix material 10 or which are present in the form of compounds containing heavy atoms.

Here, the first matrix molecules are selected from at least one of the following material classes: 4,4′-Bis(carbazole-9-yl)-2-2′dimethyl-biphenyl), TCTA (4,4′,4″-Tris(n-(naphth-2-yl)-N-phenyl-amino)triphenylamine), mCP, TCP (1,3,5-tris-carcazol-9-yl-bezen), CDBP (4,4′-Bis(carbazole-9-yl)-2,2′-dimethyl-biphenyl), DPVBi (4,4-Bis(2,2-diphenyl-ethen-1-yl)-diphenyl), Spiro-PVBi (spiro-4,4′-Bis(2,2-diphenyl-ethen-1-yl)-diphenyl), ADN (9,10-Di(2-naphthyl)anthracene), Perylene, carbazole derivates, fluorene derivates, CZ-PS, 2CzPN, m-ATP-ACR, ACRFLCN, PTZ-TRZ, CC2BP, BDPCC-TPTA, DPAA-AF, AcPmBPX. PIC-TRZ2, ACRSA, 4CzIPN, PxPmBPX, DHPT-2Bi, m-ATP-PXZ, 2PXZ-OXD, 4CzTPN, 4CzPN, 3DPA3CN, 4CzTPN-Me, Spiro-CN, 4CzTPN-Ph, DDCzIPN, PPZ-DPO, PPZ-3TPT, PPZ-4TPT, PPZ-DPS, PXZ-DPS, PXZ-TRZ, DMAC-DPS, PXZ-DPS, MAD-DPS, 2,4-bis{3-(9H-carbazole-9-yl)-9H-carb azole-9-yl}-6-phenyl-1,3,5-triazines (CC2TA), 9-(4,6-diphenyl-1,3,5-triazine-2-yl)-90-phenyl-3,30-bicarbazole (CzT).

The heavy atoms are selected from the following group: metals and metalloids of the fourth and fifth main group period, metals of the second and third sub group period, elements of the lanthanoids and actinoids.

FIG. 2 shows energy level diagrams of various emitter molecules 1 and first matrix molecules 2. FIG. 2A shows the energy level diagram of a first matrix molecule 2 and of an emitter molecule 1 of the prior art. During operation, the excitation ratio between the singlet state S_{A1} and the triplet state T_{A1} in the first matrix molecule 2 is e.g. 25:75, which results from the spin statistics of the triplet and singlet states. The excitation energy of the first matrix molecule 2 is transmitted to the emitter molecule 1 then, thereby effecting an excitation of the singlet state S_{E1} of the emitter molecule 1. The transmission of the excitation energy from the triplet state T_{A1} of the matrix molecule 2 for exciting the triplet state T_{E1} of the emitter molecule 1 is effected analogously.

en, a transition to the ground state S_{E0} occurs in the emitter molecule 1, for example. Here, transition from the singlet state S_{E1} to the ground state S_{E0} within the emitter molecule 1 is e.g. radiating and very fast, with a life span of less than 100 ns, for example. The transition from the triplet state T_{E1} to the ground state S_{E0} is strongly suppressed due to the required spin flip and can occur in radiating or non-radiating manner. The life span of the triplet state T_{E1} inside the emitter molecule 1 can be 1 ns or more, for example.

Furthermore, in the example shown in FIG. 2A, an internal quantum efficiency of the emitter layer 100 of only 25% is achieved, because only the singlet states significantly contribute to the generation of radiation during the decomposition. Although a (thermal) transition within the first matrix molecule 2 is possible between the triplet state T_{A1} and the singlet state S_{A1} (so-called inter-system crossing, ISC for short), but this transition is strongly suppressed due to the low transition moment and the large energy level split between the triplet state T_{A1} and the singlet state S_{A1} of for example more than 5,000 cm⁻¹. In total, only a small or negligible proportion of the triplet states T_{A1} will decompose into singlet states S_{A1}, which then decompose in a radiating manner in the emitter molecules 1.

In contrast to the example of FIG. 2A, the example of FIG. 2B shows a first matrix molecule 2, in which the split between the triplet state T_{A1} and the singlet state S_{A1} is selected to be smaller, the energy difference |ΔE(S_{A1}−T_{A1})| here being 2,500 cm⁻¹ at most, for example. Due to this smaller energy level split, the thermal transition from the triplet state T_{A1} to the singlet state S_{A1} within the first matrix molecule 2 is stronger than in FIG. 2A. The internal quantum efficiency of the emitter layer 100 can thereby be increased.

However, the transition probability from the triplet state T_{A1} to the singlet state S_{A1} does not exclusively depend on a low energy level split between the two states, but also on the transition moment.

FIG. 2C shows an exemplary embodiment according to the invention described herein. Here, the transition from the triplet state T_{A1} to the singlet state S_{A1} within the first matrix molecule 2 is intensified in that the heavy atoms 3 are embedded in the matrix material 10. The heavy atoms 3 cause an increased spin-orbit coupling within the first matrix molecule 2, increasing the transition moment between the two states.

For example, the time constant τ_{A} for the transition from the triplet state T_{A1} to the singlet state S_{A1} is 1·10⁻⁶ s at most then. In this way, particularly numerous, and not only 25%, of the excitations within the first matrix molecules 2 can occupy the singlet state S_{A1} and, from the singlet state S_{A1}, transit to the singlet state S_{E1} of the emitter molecule 1. The internal quantum efficiency of the entire emitter layer 100 can thereby be increased to up to 100%, preferably up to at least 90%.

FIG. 3 shows an exemplary embodiment of an organic light-emitting diode 1000, in which an emitter layer as described herein is arranged between an anode 101 and a cathode 102.

The emitter layer 100 can be electrically contacted via the anode 101 and the cathode 102 and then emit electromagnetic radiation. The anode 101 and/or cathode 102 are e.g. formed from a transparent conductive material, such as indium tin oxide, ITO for short. The anode and/or the cathode can also be formed from a metal material, such as silver, gold, aluminum, titanium.

In FIG. 3, an electron-injection layer 112 and a hole-blocking layer 122 is arranged between the cathode 102 and the emitter layer 100. Here, the electron-injection layer 112 is arranged between the cathode 102 and the hole-blocking layer 122.

A hole-injection laxer 111 and an electron-blocking layer 121 are arranged between the anode 101 and the emitter layer 100. Here, the electron-blocking layer 121 is attached between the emitter layer 100 and the hole-injection layer 111.

FIG. 3 further shows the organic layer sequence applied on to a substrate 200. In the present case, the cathode 102 faces away from the substrate 200, the anode 101 faces the substrate 200. Alternatively, this can be vice versa. The substrate 200 is for example a glass substrate, which is transparent, e.g. clear-sighted, for the radiation emitted by the emitter layer 100. In this case, the anode 101 is preferably also formed clear-sighted or transparent. The light-emitting diode 1000 then emits radiation via the substrate 200 from inside the light-emitting diode 1000 and is a so-called bottom emitter. If the anode 101 is designed to be reflective for the radiation emitted by the emitter layer 100 and the cathode 102 is designed to be transparent or clear-sighted for the radiation emitted by the emitter layer 100, the light-emitting diode 1000 of FIG. 3 is a top emitter.

The invention is not limited to the exemplary embodiments by the description by means of these exemplary embodiments. The invention rather includes any new feature as well as any combination of features, including in particular any combination of features in the claims, even if this feature or this combination is per se not explicitly stated in the patent claims or the exemplary embodiments.

This patent application claims the priority of the German patent application DE 10 2015 106 941.5, the disclosure of which is incorporated herein by reference.

### LIST OF REFERENCE CHARACTERS

1 Organic emitter molecule
2 Organic first matrix molecule
3 Heavy atom or compound containing heavy atoms
10 Organic matrix material
100 Organic emitter layer
101 Anode
102 Cathode
111 Hole injection layer
112 Electron injection layer
121 Electron blocking layer
122 Hole blocking layer
1000 Organic light-emitting diode
S_{E1} Singlet state of emitter molecule 1
T_{E1} Triplet state of emitter molecule 1
S_{A1} Singlet state of first matrix molecule 2
T_{A1} Triplet state of first matrix molecule 2
S_{E0} Ground state of emitter molecule 1
S_{A0} Ground state of first matrix molecule 2
τ_{A} Time constant

1. Organic emitter layer, comprising
organic emitter molecules each having at least one excited triplet state (T_{E1}) and at least one excited singlet state (S_{E1}),
an organic matrix material which includes organic first matrix molecules, wherein the first matrix molecules each have at least one excited triplet state (T_{A1}) and at least one excited singlet state (S_{A1}), wherein
the emitter molecules are embedded in the matrix material,
during operation of the emitter layer, the triplet states (T_{A1}) and the singlet states (S_{A1}) of the first matrix molecules are excited,
during operation, the excitation energy of these states is at least partially transmitted to the emitter molecules so that the singlet states (S_{E1}) are excited in the emitter molecules,
during operation, a transition from the singlet states (S_{E1}) of the emitter molecules into the ground state (S_{EO}) of the emitter molecules occurs while at least partially emitting electromagnetic radiation,
in the first matrix molecules, the absolute value of the energy level difference |ΔE(S_{A1}−T_{A1})| between the triplet state (T_{A1}) and the singlet state (S_{A1}) is 2,500 cm⁻¹ at most,
a time constant τ_{A} for the transition from the triplet state (T_{A1}) into the singlet state (S_{A1}) in the first matrix molecules is at most 1·10⁻⁶ s,
heavy atoms with an atomic number of at least 16 are intentionally introduced in the matrix material.

2. Organic emitter layer according to claim 1,
wherein the heavy atoms cause an increased spin-orbit coupling in the first matrix molecules, so that the time constant τA is set.

3. Organic emitter layer according to claim 1, wherein
the emitter molecules are selected from the group of the following molecules: DCM (4-(Dicyanomethylene)-2-methyl-6-(p-dimethylamino-styryle)4H-pyran), DCM2 (4-(dicyanomethylene)-2-methyl-6-(julolidin-4-yl-vinyl)-4H-pyran), Rubrene (5,6,11,12-tetraphenyl-naphthacen), coumarin (C545T), TBSA (9,10-Bis[(2″,7″″-di-t-butyl)-9′,9″-spirobifluorenyl]anthracene), Zn-complexes, Cu-complexes, Aluminum-tris(8-hydroxyquinoline),
the first matrix molecules are selected from the group of the following molecules: 4,4′-Bis(carbazole-9-yl)-2-2′dimethyl-biphenyl), TCTA (4,4′,4″-Tris(n-(naphth-2-yl)-N-phenyl-amino)triphenylamine), mCP, TCP (1,3,5-tris-carcazol-9-yl-bezene), CDBP (4,4′-Bis(carbazole-9-yl)-2,2′-dimethyl-biphenyl), DPVBi (4,4-Bis(2,2-diphenyl-ethen-1-yl)-diphenyl), Spiro-PVBi (spiro-4,4′-Bis(2,2-diphenyl-ethen-1-yl)-diphenyl), ADN (9,10-Di(2-naphthyl)anthracene), Perylene, carbazole derivates, fluorene derivates, CZ-PS, 2CzPN, m-ATP-ACR, ACRFLCN, PTZ-TRZ, CC2BP, BDPCC-TPTA, DPAA-AF, AcPmBPX. PIC-TRZ2, ACRSA, 4CzIPN, PxPmBPX, DHPT-2Bi, m-ATP-PXZ, 2PXZ-OXD, 4CzTPN, 4CzPN, 3DPA3CN, 4CzTPN-Me, Spiro-CN, 4CzTPN-Ph, DDCzIPN, PPZ-DPO, PPZ-3TPT, PPZ-4TPT, PPZ-DPS, PXZ-DPS, PXZ-TRZ, DMAC-DPS, PXZ-DPS, MAD-DPS, 2,4-bis{3-(9H-carbazole-9-yl)-9H-carbazole-9-yl}-6-phenyl-1,3,5-triazines (CC2TA), 9-(4,6-diphenyl-1,3,5-triazine-2-yl)-90-phenyl-3,30-bicarbazole (CzT),
the heavy atoms are selected from the group of the following elements: S, Br, I, Kr, Xe, metals and metalloids of the third, fourth and fifth main group period, metals of the first, second and third sub group period, elements of the lanthanoids and actinoids.

4. Organic emitter layer according to claim 3,
wherein the heavy atoms are selected from the following group:
metals and metalloids of the fourth and fifth main group period, metals of the second and third sub group period, elements of the lanthanoids and actinoids.

5. Organic emitter layer according to claim 1,
wherein the time constant τA for the transition from the triplet state (T_{A1}) to the singlet state (S_{A1}) in the first matrix molecules is 1·10⁻⁸ s at most.

6. Organic emitter layer according to claim 1,
wherein during operation, at least 80% of the occurring primary excitations in the emitter layer are excitations of the singlet states (S_{A1}) of the first matrix molecules.

7. Organic emitter layer according to claim 1,
wherein the first matrix molecules are not provided or configured for the emission of electromagnetic radiation during operation.

8. Organic emitter layer according to claim 7, wherein in the emitter molecules the absolute value of the energy level difference |ΔE(S_{E1}−T_{E1})| between the triplet state (T_{E1}) and the singlet state (S_{E1}) is at least 2,500 cm⁻¹.

9. Organic emitter layer according to claim 1,
wherein
the triplet state (T_{A1}) and the singlet state (S_{A1}) in the first matrix molecules are in each case the first excited triplet and singlet state above the ground state (S_{A0}) of the first matrix molecule,
the triplet state (T_{E1}) and the singlet state (S_{E1}) in the emitter molecules are in each case the first excited triplet and singlet state above the ground state (S_{E0}) of the emitter molecule,
during operation of the emitter layer, at least 90% of the transitions in the emitter molecules are transitions from the singlet state (S_{A1}) to the ground state (S_{E0}).

10. Organic emitter layer according to claim 1,
wherein the heavy atoms are free or practically free atoms in the matrix material.

11. Organic emitter layer according to claim 1,
wherein the heavy atoms are present in compounds containing heavy atoms and are coordinatively or covalently bound to organic or inorganic ligands.

12. Organic emitter layer according to claim 1,
wherein the proportion of heavy atoms and/or the compounds containing heavy atoms in the emitter layer is at least 3 vol.-%.

13. Organic emitter layer according to claim 1,
wherein the proportion of emitter molecules in the emitter layer is between 1 vol.-% and 40 vol.-% inclusive.

14. Organic light-emitting diode with
at least one emitter layer according to claim 1,
an anode and a cathode, between which the emitter layer is arranged.

15. Organic light-emitting diode according to claim 14,
wherein the anode and/or the cathode are transparent for the radiation emitted by the emitter layer.

16. Organic light-emitting diode according to claim 14,
wherein an electron-injection layer and/or a hole-blocking layer is arranged between the cathode and the emitter layer, and/or
wherein a hole-injection layer and/or an electron-blocking layer is arranged between the anode and the emitter layer.

17. Use of heavy atoms with an atomic number of at least 16 in an organic emitter layer of an organic light-emitting diode,
wherein
the organic light-emitting diode includes the organic emitter layer and the emitter layer produces electromagnetic radiation during the intended operation,
the organic emitter layer includes an organic matrix material with organic first matrix molecules,
organic emitter molecules are embedded in the matrix material,
the heavy atoms are introduced in the organic matrix material as free or practically free atoms or in the form of compounds containing heavy atoms,
the proportion of heavy atoms and/or the proportion of the compounds containing heavy atoms in the emitter layer is at least 3 vol.-%,
the first matrix molecules are selected from at least one of the following material classes: 4,4′-Bis(carbazole-9-yl)-2-2′dimethyl-biphenyl), TCTA (4,4′,4″-Tris(n-(naphth-2-yl)-N-phenyl-amino)triphenylamine), mCP, TCP (1,3,5-tris-carcazol-9-yl-bezene), CDBP (4,4′-Bis(carbazole-9-yl)-2,2′-dimethyl-biphenyl), DPVBi (4,4-Bis(2,2-diphenyl-ethen-1-yl)-diphenyl), Spiro-PVBi (spiro-4,4′-Bis(2,2-diphenyl-ethen-1-yl)-diphenyl), ADN (9,10-Di(2-naphthyl)anthracene), Perylene, carbazole derivates, fluorene derivates, CZ-PS, 2CzPN, m-ATP-ACR, ACRFLCN, PTZ-TRZ, CC2BP, BDPCC-TPTA, DPAA-AF, AcPmBPX. PIC-TRZ2, ACRSA, 4CzIPN, PxPmBPX, DHPT-2Bi, m-ATP-PXZ, 2PXZ-OXD, 4CzTPN, 4CzPN, 3DPA3CN, 4CzTPN-Me, Spiro-CN, 4CzTPN-Ph, DDCzIPN, PPZ-DPO, PPZ-3TPT, PPZ-4TPT, PPZ-DPS, PXZ-DPS, PXZ-TRZ, DMAC-DPS, PXZ-DPS, MAD-DPS, 2,4-bis{3-(9H-carbazole-9-yl)-9H-carbazole-9-yl}-6-phenyl-1,3,5-triazines (CC2TA), 9-(4,6-diphenyl-1,3,5-triazine-2-yl)-90-phenyl-3,30-bicarbazole (CzT),
the heavy atoms are selected from the following group: metals and metalloids of the third, fourth and fifth main group period, metals of the first, second and third sub group period, elements of the lanthanoids and actinoids,
the absolute value of the energy level difference |ΔE(S_{A1}−T_{A1})| between a first excited triplet state (T_{A1}) and a first excited singlet state (S_{A1}) of the first matrix molecules is 2,500 cm⁻¹ at most.

18. Organic emitter layer, comprising
organic emitter molecules each having at least one excited triplet state (T_{E1}) and at least one excited singlet state (S_{E1}),
an organic matrix material, which includes organic first matrix molecules, wherein the first matrix molecules each have at least one excited triplet state (T_{A1}) and at least one excited singlet state (S_{A1}), wherein
the emitter molecules are embedded in the matrix material,
during operation of the emitter layer, the triplet states (T_{A1}) and the singlet states (S_{A1}) of the first matrix molecules are excited,
during operation, the excitation energy of these states is at least partially transmitted to the emitter molecules so that the singlet states (S_{E1}) are excited in the emitter molecules,
during operation, a transition from the singlet states (S_{E1}) of the emitter molecules into the ground state (S_{EO}) of the emitter molecules occurs while at least partially emitting electromagnetic radiation,
in the first matrix molecules, the absolute value of the energy level difference |ΔE(S_{A1}−T_{A1})| between the triplet state (T_{A1}) and the singlet state (S_{A1}) is 2,500 cm⁻¹ at most,
a time constant τ_{A} for the transition from the triplet state (T_{A1}) into the singlet state (S_{A1}) in the first matrix molecules is at most 1·10⁻⁶ s,
heavy atoms with an atomic number of at least 16 are intentionally introduced in the matrix material, wherein the heavy atoms are selected from the group of the following elements: metals and metalloids of the third, fourth and fifth main group period, metals of the first, second and third sub group period, elements of the lanthanoids and actinoids.
